(19) United States
(12) Patent Application Publication
(10) Pub. No.: US 2022/0407477 A1
(43) Pub. Date: Dec. 22, 2022

(54) CLASS D AMPLIFIER MODULE

(71) Applicant: ROHM CO., LTD., Kyoto-shi (JP)

(72) Inventor: Hirotsugu EGO, Kyoto-shi (JP)

(21) Appl. No.: 17/874,359

(22) Filed: Jul. 27, 2022

Related U.S. Application Data
(63) Continuation of application No. PCT/JP2021/001638, filed on Jan. 19, 2021.

(30) Foreign Application Priority Data
Jan. 27, 2020 (JP) 2020-011038

(51) Int. Cl. H03F 3/217

(52) U.S. Cl. CPC H03F 3/2171; H03F 2200/03

(57) ABSTRACT

A Class D amplifier module includes a semiconductor chip and n inductors. The semiconductor chip includes n output stages, n high-side drivers, and n low-side drivers. The semiconductor chip and the n inductors are housed in a single package and operate according to a control signal received from an external processor.

### CROSS REFERENCE TO RELATED APPLICATIONS

This application is a continuation under 35 U.S.C. § 120 of PCT/JP2021/001638, filed Jan. 19, 2021, which is incorporated herein by reference, and which claimed priority to Japanese Application No. 2020-011038, filed Jan. 27, 2020. The present application likewise claims priority under 35 U.S.C. § 119 to Japanese Application No. 2020-011038, filed Jan. 27, 2020, the entire content of which is also incorporated herein by reference.

### BACKGROUND

### 1. Technical Field

The present disclosure relates to an audio system.

### 2. Description of the Related Art

An audio amplifier circuit is employed in order to amplify a weak audio signal so as to drive an electroacoustic conversion element such as speakers or headphones. FIG. 1 is a circuit diagram of an audio system 100r. In addition to an electroacoustic conversion element 102, the audio system 100r includes an audio amplifier IC (Integrated Circuit) 200r and filters 104_{P/N}. The electroacoustic conversion element 102 is coupled to the audio amplifier IC 200r by a BLT (Bridged Transformer less/Bridge-Tied Load) connection.

The audio amplifier IC 200r is provided with an OUTP terminal and an OUTN terminal. A filter 104_{P} is provided between a positive terminal + and the OUTP terminal of the electroacoustic conversion element 102. Furthermore, a filter 104_{N} is provided between a negative terminal − and the OUTN terminal of the electroacoustic conversion element 102. Each filter 104 is configured as a first-order filter including a series inductor L1 and a shunt capacitor C1.

The audio amplifier IC 200r includes Class D amplifiers 202_{P/N} and a pulse modulator 206. The pulse modulator 206 receives an analog or digital audio signal S1, and pulse-modulates the audio signal S1 so as to generate pulse signals S2_{P/N}.

The Class D amplifiers 202_{P} and 202_{N} each include a driver 203 and an output stage 204. The driver 203 drives the output stage 204 according to the pulse signal S2_{P} or S2_{N}.

The audio system 100r shown in FIG. 1 is configured as a four-channel system. A circuit of such a four-channel system is integrated in the audio amplifier IC 200r.

As a result of investigating the audio system 100r shown in FIG. 1, the present inventor has come to recognize the following problems.

### Problem 1

In the audio system 100r, each output pin OUTP/OUTN of the audio amplifier IC 200 and the corresponding filter 104_{P}/104_{N} are coupled via a switching line 108. The large output signals Vo+ and Vo− that occur at the respective output pins OUTP/OUTN are transmitted via the switching lines 108. With this, a large current flows through each switching line 108.

In the audio system 100r shown in FIG. 1, the switching line 108 is configured as wiring on a printed circuit board or a cable having a long length. Such a long switching line 108 involves an unintended parasitic inductance component, which can become a factor of degraded sound quality.

### Problem 2

In a case in which a large signal having a switching waveform propagates through such a long switching line 108, such an arrangement has a problem in that radiation noise can readily occur as Electromagnetic Interference (EMI) noise.

### Problem 3

In the audio system 100r shown in FIG. 1, Class D amplifiers 202 are integrated in the audio amplifier IC 200 for four channels. Such Class D amplifiers 202 each become a heat source. Accordingly, in a case in which multiple Class D amplifiers 202 are integrated on the same semiconductor chip, this leads to a problem of heat generated by the audio amplifier IC 200r. This requires a countermeasure for releasing heat such as a large-size heatsink coupled to the audio amplifier IC 200r, leading to an increased cost.

### Problem 4

In a case of using only two channels from among the four channels of the audio system 100r shown in FIG. 1, the Class D amplifiers 202 for the remaining two channels are wasted.

### SUMMARY

The present disclosure has been made in order to solve such problems.

An embodiment of the present disclosure relates to a Class D amplifier module. The Class D amplifier module includes: a semiconductor chip including n (n≥1) output stages each including a high-side transistor and a low-side transistor, n high-side drivers each structured to drive the high-side transistor of a corresponding one of the n output stages, n low-side drivers each structured to drive the low-side transistor of a corresponding one of the n output stages, and n switching terminals respectively coupled to outputs of the n output stages; and n inductors each having one end coupled to the switching terminal of the corresponding one of the n output stages. The Class D amplifier module is housed in a single package and is structured to operate according to a control signal from an external processor.

It should be noted that any combination of the components described above, or manifestation of the present disclosure may be mutually substituted between a method, apparatus, and so forth, which are also effective as an embodiment of the present disclosure.

### BRIEF DESCRIPTION OF THE DRAWINGS

FIG. 1 is a circuit diagram of an audio system.

FIG. 2 is a block diagram showing an audio system including Class D amplifier modules according to an embodiment.

FIG. 3A and FIG. 3B are diagrams showing simulation results of heat generation of the audio systems shown in FIG. 1 and FIG. 2.

FIG. 4A and FIG. 4B are diagrams each explaining one of the advantages of the Class D amplifier module shown in FIG. 2.

FIG. 5 is a perspective diagram showing an example configuration of the Class D amplifier module.

FIG. 6 is a circuit diagram of a Class D amplifier module according to a modification 1.

FIG. 7 is a block diagram showing an audio system according to a modification 3.

FIG. 8 is a block diagram showing an automobile provided with an audio system.

### DETAILED DESCRIPTION

### Outline of Embodiments

An embodiment disclosed in the present specification relates to a Class D amplifier module. The Class D amplifier module includes a semiconductor chip and n inductors housed in a single package. The Class D amplifier module is structured to operate according to a control signal from an external processor. The semiconductor chip includes n (n≥1) output stages each including a high-side transistor and a low-side transistor, n high-side drivers each structured to drive the high-side transistor of a corresponding one of the n output stages, n low-side drivers each structured to drive the low-side transistor of a corresponding one of the n output stages, and n switching terminals respectively coupled to the outputs of the n output stages. The n inductors are each having one end coupled to the switching terminal of the corresponding one of the n output stages.

With this embodiment, each switching line that couples an output stage and an inductor is within the package, thereby allowing the length thereof to be reduced. This is capable of suppressing the effects of parasitic inductance, thereby providing improved sound quality.

With such an arrangement in which each switching line is within the package so as to allow it to have a reduced length, this is capable of suppressing radiation of EMI noise from each switching line.

Furthermore, this allows the output stages of the Class D amplifiers, which each generate heat, to be arranged in a distributed manner for each module. This facilitates the countermeasure for releasing heat, thereby providing a reduced cost.

Moreover, by increasing or decreasing the number of the Class D amplifier modules, this allows systems with a different number of channels to be designed.

Also, the Class D amplifier module may further include n capacitors each arranged between the ground and the other end of the corresponding one of the n inductors.

Also, the high-side transistor may be structured as an NMOS transistor. Also, the semiconductor chip may further include: a voltage source structured to generate a constant voltage; n bootstrap terminals; and n rectifier elements each having an anode receiving the constant voltage and a cathode coupled to a corresponding one of the n bootstrap terminals. Also, the Class D amplifier module may include n bootstrap capacitors each having one end coupled to a corresponding one of the n bootstrap terminals, and the other end coupled to a corresponding one of the n switching terminals.

Also, an arrangement may be made in which n=2. Also, the two output stages may be BTL-connected.

### Embodiments

Description will be made below regarding the embodiments with reference to the drawings. In each drawing, the same or similar components, members, and processes are denoted by the same reference numerals, and redundant description thereof will be omitted as appropriate. The embodiments have been described for exemplary purposes only and are by no means intended to restrict the present disclosure. Also, it is not necessarily essential for the present disclosure that all the features or a combination thereof be provided as described in the embodiments.

In the present specification, the state represented by the phrase “the member A is coupled to the member B” includes a state in which the member A is indirectly coupled to the member B via another member that does not substantially affect the electric connection between them, or that does not damage the functions or effects of the connection between them, in addition to a state in which they are physically and directly coupled.

Similarly, the state represented by the phrase “the member C is provided between the member A and the member B” includes a state in which the member A is indirectly coupled to the member C, or the member B is indirectly coupled to the member C via another member that does not substantially affect the electric connection between them, or that does not damage the functions or effects of the connection between them, in addition to a state in which they are directly coupled.

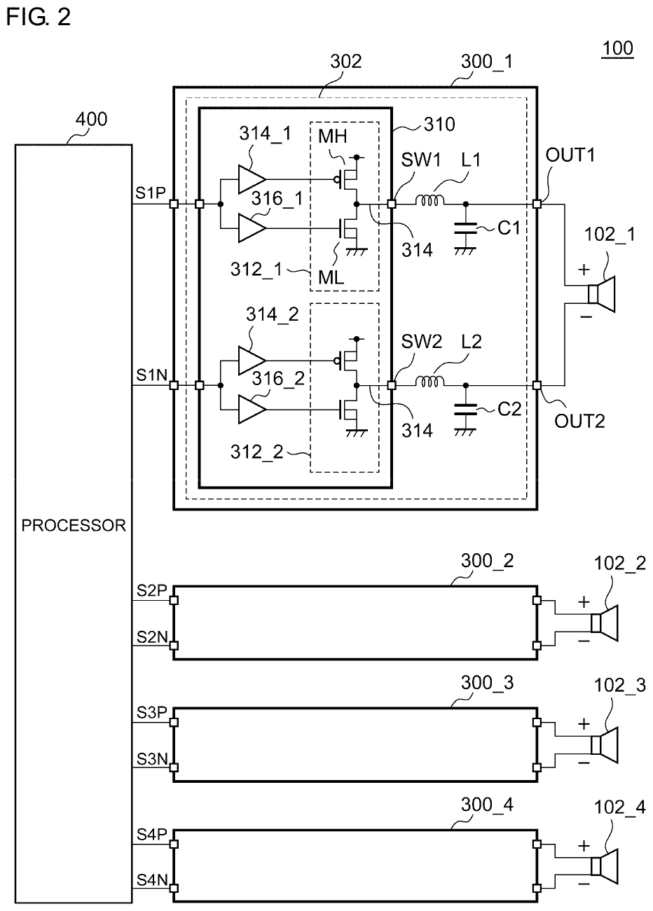

FIG. 2 is a block diagram showing an audio system 100 provided with a Class D amplifier module 300 according to an embodiment.

The audio system 100 is configured as an m-channel (m≥1) system including m electroacoustic conversion elements 102_1 through 102_m, m Class D amplifier modules 300_1 through 300_m, and a processor 400. Description will be made in the present embodiment regarding an arrangement in which m=4.

The processor 400 generates control pulses S1P/S1N through SmP/SmN corresponding to the m Class D amplifier modules 300_1 through 300_m. Each Class D amplifier module 300_i (i=1, . . . , m) drives the corresponding electroacoustic conversion element 102_i according to the control pulse.

The Class D amplifier modules 300_1 through 300_m each include a semiconductor chip 310, n (n≥2) inductors L1 through Ln, and n capacitors C1 through Cn, which are mounted on a support substrate 302 and are housed in a single package. Description will be made in the present embodiment regarding an arrangement in which n=2.

Each semiconductor chip 310 includes n output stages 312_1 through 312_n, n high-side drivers 314_1 through 314_n, n low-side drivers 316_1 through 316_n, and n switching terminals SW1 through SWn, which are integrated on a single semiconductor substrate.

Each output stage 312_j (j=1, . . . , n) includes a high-side transistor MH and a low-side transistor ML. Each electroacoustic conversion element 102_i is BTL-connected to the output stages 312_1 and 312_2 of the corresponding Class D amplifier module 300_i.

Each high-side driver 314_j drives the high-side transistor MH of the corresponding output stage 312_j from among the n output stages 312. Each low-side driver 316_j drives the low-side transistor ML of the corresponding output stage 312_j from among the n output stages 312.

One end of each inductor Lj is coupled to a switching terminal SWj of the corresponding output stage 312_j from among the n output stages 312. Furthermore, a capacitor Cj is provided between the other end of the corresponding inductor Lj and the ground, which forms a low-pass filter together with the inductor Lj.

The above is the configuration of the Class D amplifier module 300. With such a Class D amplifier module 300, such an arrangement is capable of providing at least one from among the advantages 1 through 4.

### Advantage 1

With the Class D amplifier module 300 shown in FIG. 2, a switching line 304 that couples the switching terminal SWj of the output stage 312 and the inductor L1 is within the package of the Class D amplifier module 300. This allows the switching line 304 to have a reduced length. This is capable of suppressing the effects of the parasitic inductance due to the switching line 304, thereby providing improved sound quality.

### Advantage 2

Furthermore, with such an arrangement in which the switching line 304 is within the package, this allows the length thereof to be reduced. This is capable of suppressing the radiation of EMI noise from the switching line 304. With such an arrangement shown in FIG. 2, the pulse signals SiP/SiN are supplied to each i-th (i=1, . . . , m) Class D amplifier module 300_i from the processor 400 via wiring formed on the printed circuit board. However, the pulse signals SiP/SiN are each configured as a small signal. Accordingly, this arrangement does not readily cause a problem of EMI noise.

### Advantage 3

With the audio system 100 shown in FIG. 2, the output stages 312 of the Class D amplifiers which are each a heat source can be arranged in a distributed manner for each Class D amplifier module 300. That is to say, because the heat sources can be arranged in a distributed manner, this facilitates the countermeasure for releasing heat, thereby allowing the cost to be reduced.

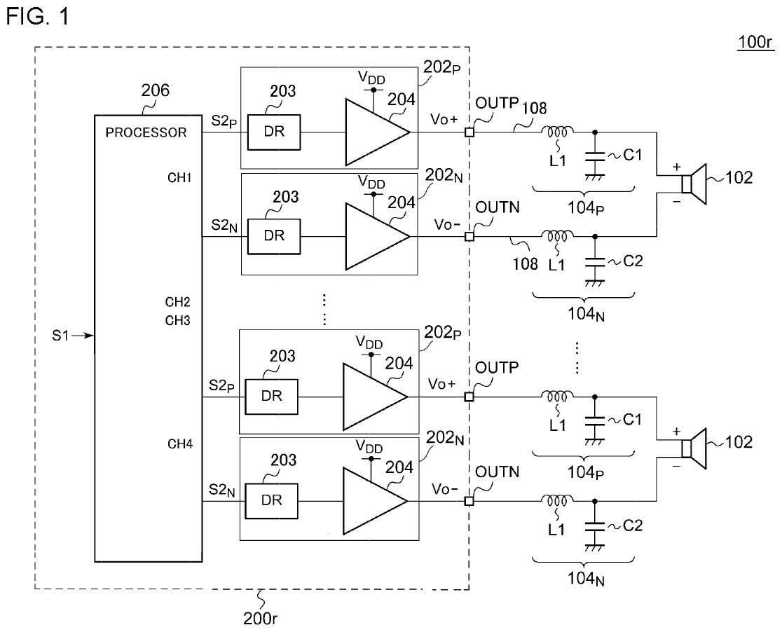

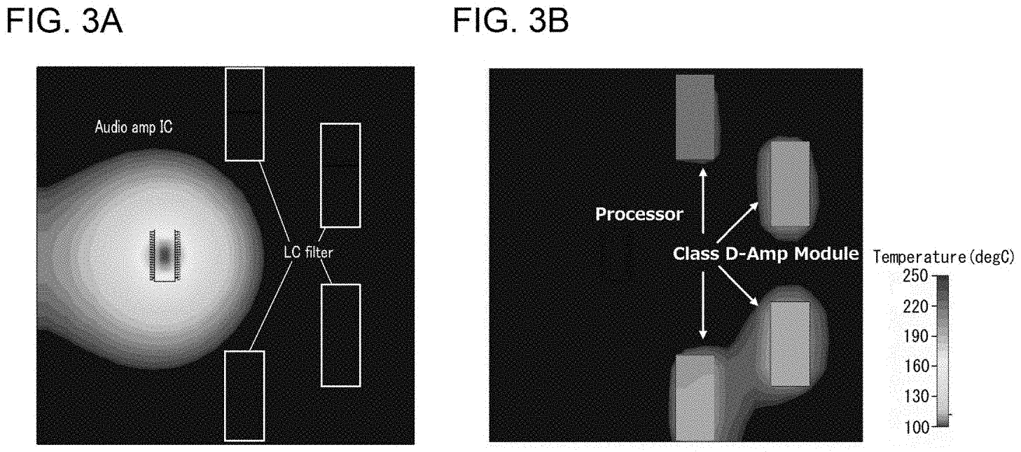

FIG. 3A and FIG. 3B are diagrams showing simulation results of heat generation in the audio system 100r shown in FIG. 1 and the audio system 100 shown in FIG. 2, respectively. Both simulations were made assuming that the audio system has a four-channel configuration and the Class D amplifier of each channel is modeled as a 25 W heat generator.

Description will be made with reference to FIG. 3A regarding investigation of the audio system 100r shown in FIG. 1. With this arrangement, 100 W (=25 W×4 channels) of heat generation is concentrated in the audio amplifier IC. As a result, the peak temperature reaches up to 250° C. Accordingly, such an arrangement requires a countermeasure for releasing heat such as a large-size heatsink.

Description will be made with reference to FIG. 3B regarding the audio system 100 shown in FIG. 2. In this example, instead of arranging the LC filters in the regions as shown in FIG. 3A the multiple Class D amplifier modules 300_1 through 300_m are arranged in these regions in a distributed manner. This arrangement is capable of suppressing a temperature increase of each Class D amplifier module 300 to on the order of 120° C. Accordingly, this allows the countermeasure for releasing heat to be dramatically simplified, thereby allowing the cost to be reduced.

### Advantage 4

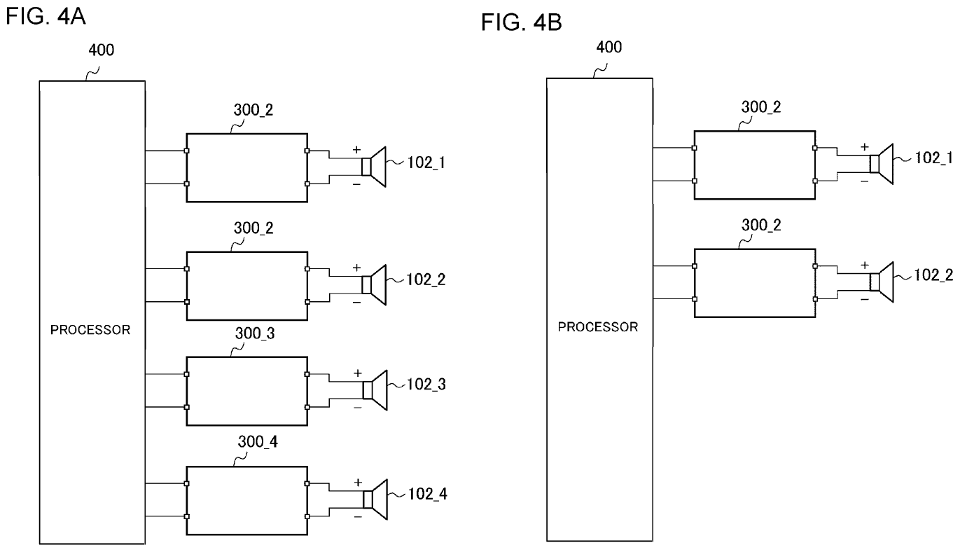

FIG. 4A and FIG. 4B are diagrams for explaining one of the advantages of the Class D amplifier module 300 shown in FIG. 2. FIG. 4A shows a four-channel audio system 100. FIG. 4B shows a two-channel audio system 100. As shown in the drawings, this allows the number m of the Class D amplifier modules 300 to be increased and reduced according to the number of channels m. With this, even if there is a difference in the number m of channels between systems, this arrangement is capable of supporting such systems.

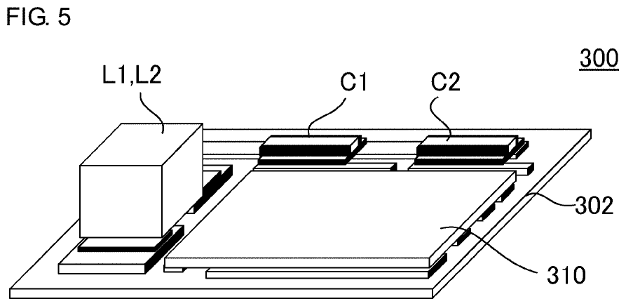

Next, description will be made regarding a specific example configuration of the Class D amplifier module 300. FIG. 5 is a perspective diagram showing an example configuration of the Class D amplifier module 300. In this example, the inductors L1 and L2 are configured as a single chip component. The layout of the semiconductor chip 310 and the chip components C1, C2, L1, and L2 mounted on the support substrate 302 is not restricted in particular. In this example, the semiconductor chip 310 and multiple chip components are mounted on the same face of the support substrate 302. However, the present invention is not restricted to such an arrangement. Also, such components may be mounted in a three-dimensional manner. Also, a member other than the support substrate 302, e.g., a lead frame, may be employed as a base member so as to form a package.

The above-described embodiments have been described for exemplary purposes only, and are by no means intended to be interpreted restrictively. Rather, it can be readily conceived by those skilled in this art that various modifications may be made by making various combinations of the aforementioned components or processes, which are also encompassed in the technical scope of the present disclosure or the present invention. Description will be made below regarding such modifications.

### Modification 1

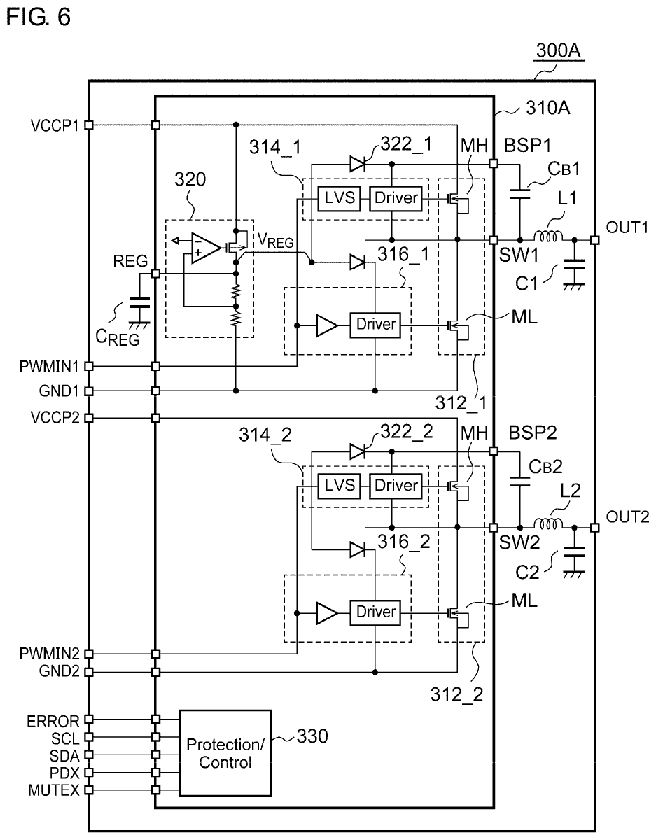

FIG. 6 is a circuit diagram of a Class D amplifier module 300A according to a modification 1. In this modification, the high-side transistor MH is configured as an N-channel FET. Description will be made in this example regarding an arrangement in which N=2. The Class D amplifier module 300A includes a semiconductor chip 310A, inductors L1 and L2, capacitors C1 and C2, and n bootstrap capacitors C_{B}1 and C_{B}2. Each bootstrap capacitor C_{B}j is coupled between a corresponding bootstrap terminal BSPj and the corresponding switching terminal SWj.

The semiconductor chip 310A includes n output stages 312, n high-side drivers 314, n low-side drivers 316, n rectifier elements 322, a, and a constant voltage source 320.

The constant voltage source 320 generates a constant voltage V_{REG}. The Class D amplifier module 300A may include a capacitor C_{REG} for smoothing the constant voltage V_{REG}. The constant voltage V_{REG} is supplied to the anode of each rectifier element 322_j. The cathode of each rectifier element 322_j is coupled to the corresponding bootstrap terminal BSPj. The rectifier element 322_j and the bootstrap capacitor C_{B}j form a bootstrap circuit so as to generate the power supply voltage for the high-side driver 314j.

A protection/control circuit 330 is configured as a block for integrally controlling the Class D amplifier module 300A including a communication interface (e.g., I²C) that allows communication with an external microcontroller, a protection circuit for the semiconductor chip 310A, etc. Upon detecting an abnormality, the protection/control circuit 330 notifies an external microcontroller or the like via an ERROR pin. Furthermore, the protection/control circuit 330 is coupled to the external microcontroller via a clock pin SCL and a data pin SDA and receives a control signal from the external microcontroller. The protection/control circuit 330 controls the startup/shutdown of the Class D amplifier module 300A according to a power-down signal (inverted logic) input to a PDX pin. Furthermore, the protection/control circuit 330 switches the state between the mute state and the unmute state according to a mute signal (inverted logic) input to a MUTEX pin.

### Modification 3

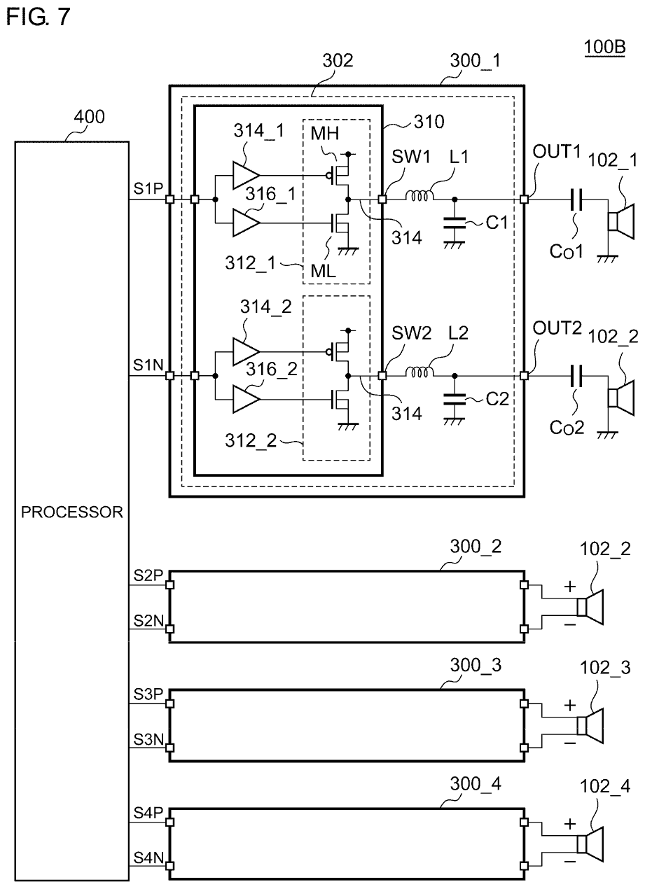

Description has been made in the embodiment regarding an arrangement in which each electroacoustic conversion element 102 is BTL-connected to two output stages 312 (n=2). However, the present invention is not restricted to such an arrangement. FIG. 7 is a block diagram showing an audio system 100B according to a modification 3. In this modification 3, one electroacoustic conversion element 102 is single-end coupled to one output stage 312. A decoupling capacitor Co is coupled as an external component between the output pin of the Class D amplifier module 300 and the electroacoustic conversion element 102. It should be noted that, in a case in which the Class D amplifier module 300 is configured as a dedicated component for single-ended coupling, the capacitor Co may be built into the Class D amplifier module 300.

### Modification 4

In a modification 4, the n capacitors C1 through Cn may each be provided to the Class D amplifier module 300 as an external component.

### Modification 5

Description has been made in the embodiment regarding an arrangement in which one Class D amplifier module 300 includes two (n=2) built-in output stages 312. However, the present invention is not restricted to such an arrangement. Also, an arrangement may be made in which n=1 or n≥3.

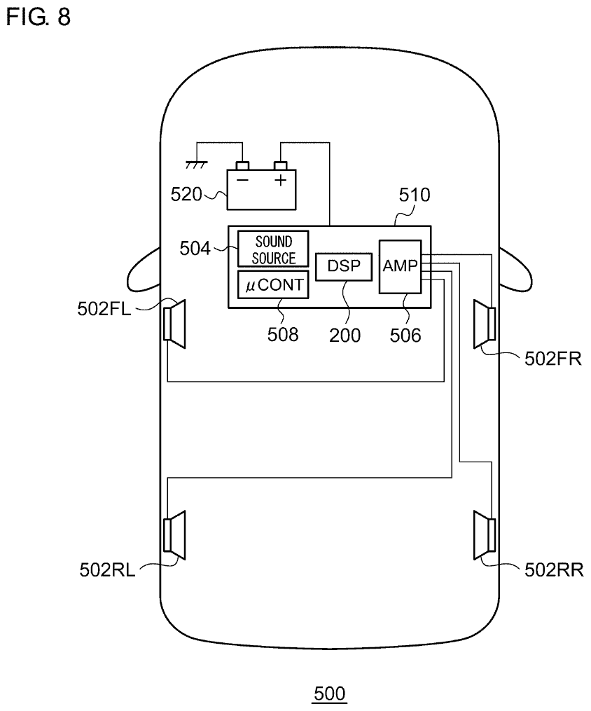

Lastly, description will be made regarding an example of the usage of the audio system 100. FIG. 8 is a block diagram showing an automobile (in-vehicle audio apparatus) 500 provided with the audio system 100. The in-vehicle audio apparatus 500 is configured as a four-channel (front-right (FR), rear-right (RR), front-left (FL), and rear-left (RL)) system including multiple speakers 502FR, 502RR, 502FL, and 502RL that correspond to the four channels. The in-vehicle audio apparatus 500 may be configured as a 5.1 channel system further including a center channel and a subwoofer channel. Also, the in-vehicle audio apparatus 500 may support further additional channels.

The sound source 504 is configured as a CD player, DVD player, Blu-ray player, HDD/silicon audio player, radio tuner, or the like. The sound source 504 plays back an analog or digital audio signal. The DSP 200 receives an audio signal from the sound source 504 and applies various kinds of digital signal processing to the audio signal thus received. The audio signal thus subjected to the processing by the DSP 200 is input to an amplifier block 506. The amplifier block 506 corresponds to the audio system 100 described above and includes a processor 400 and multiple Class D amplifier modules 300. The amplifier block 506 amplifies the analog audio signals of the respective channels, so as to drive the corresponding speakers 502. A microcontroller 508 integrally controls blocks such as the DSP 200 or the like. The sound source 504, the microcontroller 508, the DSP 200, and the amplifier block 506 receive a supply of power from a battery 520 so as to operate. The sound source 504, the microcontroller 508, the DSP 200, and the amplifier block 506 may be built into a head unit 510.

What is claimed is:

1. A Class D amplifier module comprising:
a semiconductor chip comprising:
n (n≥1) output stages each comprising a high-side transistor and a low-side transistor;
n high-side drivers each structured to drive the high-side transistor of a corresponding one of the n output stages;
n low-side drivers each structured to drive the low-side transistor of a corresponding one of the n output stages; and
n switching terminals respectively coupled to outputs of the n output stages, and
n inductors each having one end coupled to the switching terminal of the corresponding one of the n output stages,
wherein the Class D amplifier module is housed in a single package and is structured to operate according to a control signal from an external processor.

2. The Class D amplifier module according to claim 1, further comprising n capacitors each arranged between a ground and the other end of the corresponding one of the n inductors.

3. The Class D amplifier module according to claim 1, wherein the high-side transistor is structured as an NMOS transistor,
wherein the semiconductor chip further comprises:
a voltage source structured to generate a constant voltage;
n bootstrap terminals; and
n rectifier elements each having an anode receiving the constant voltage and a cathode coupled to a corresponding one of the n bootstrap terminals,
and wherein the Class D amplifier module comprises n bootstrap capacitors each having one end coupled to a corresponding one of the n bootstrap terminals, and the other end coupled to a corresponding one of the n switching terminals.

4. The Class D amplifier module according to claim 1, wherein n=2,
and wherein the two output stages are BTL-connected.

5. An audio system comprising:
a processor;
m (m≥1) electroacoustic conversion elements; and
m Class D amplifier modules according to claim 4, each structured to drive a corresponding one of the m electroacoustic conversion elements.

6. An automobile provided with the audio system according to claim 5.
